(19) United States
(12) Patent Application Publication
(10) Pub. No.: US 2007/0210380 A1
(43) Pub. Date: Sep. 13, 2007

(54) BODY CONNECTION STRUCTURE FOR SOI MOS TRANSISTOR

(76) Inventor: Jin-Yuan Lee, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,181

(22) Filed: Mar. 10, 2006

(51) Int. Cl. H01L 27/12

(52) U.S. Cl. 257/347

(57) ABSTRACT

A body connection structure for a SOI MOS transistor is described, including a first and a second control transistors. The first control transistor includes a gate electrically connecting with the gate of the SOI MOS transistor, a first S/D region electrically connecting with the first S/D region of the SOI MOS transistor and a second S/D region electrically connecting with the body layer of the SOI MOS transistor. The second control transistor includes a gate electrically connecting with the gate of the SOI MOS transistor, a first S/D region electrically connecting with the second S/D region of the SOI MOS transistor and a second S/D region electrically connecting with the body layer of the SOI MOS transistor.

### BACKGROUND OF THE INVENTION

1. Field of the Invention

The present invention relates to a semiconductor structure. More particularly, the present invention relates to a body connection structure for a semiconductor-on-insulator (SOI) MOS transistor.

2. Description of the Related Art

Semiconductor-on-insulator (SOI) devices are widely used for their excellent electrical properties including lower threshold voltage, smaller parasitic capacitance, less current leakage and good switching property, etc. An SOI substrate essentially includes a substrate, an insulator on the substrate and a semiconductor body layer on the insulator. FIG. 1 is a circuit diagram of a conventional SOI MOS transistor, wherein the substrate, the insulator and the body layer together form a capacitor.

As the above SOI MOS transistor is an NMOS transistor, at the turn-on stage, the body layer is gradually charged to more positive potential by the hot carrier effect, so that the threshold voltage of the NMOS becomes lower gradually and the channel current becomes larger gradually. As the SOI MOS transistor is a PMOS transistor, the body layer is gradually charged to more negative potential by the hot carrier effect and the channel current becomes larger gradually at the turn-on stage.

However, since the threshold voltage of a transistor depends on the potential of its body and the potential of the body depends on the previous state of the transistor, the circuit design become more difficult. Meanwhile, since at the turn-off stage the charge amount in the body layer depends on the time after the previous use, the magnitude of the channel current cannot be well predicted.

FIG. 2 shows a circuit diagram of another conventional SOI MOS transistor with its body connection structure, the transistor being exemplified as an NMOS transistor. The gate of the SOI NMOS transistor is electrically connected with the gates of two dummy NMOS transistors. One source/drain (S/D) of the SOI transistor is electrically connected with one S/D of the first dummy NMOS and the other S/D of the same with one S/D of the second dummy NMOS, while the other S/D of each of the two dummy NMOS transistors forms a PN diode with the body layer of the SOI NMOS transistor. The body layer is electrically connected to ground or certain potential.

However, since the body layer is coupled to a fixed potential, there is no floating body effect and therefore no extra driving current gain.

### SUMMARY OF THE INVENTION

In view of the foregoing, this invention provides a body connection structure for a SOI MOS transistor, which can effectively charge the body layer of the SOI MOS transistor to increase the channel current during the turn-on stage.

The above SOI MOS transistor includes a substrate, an insulator on the substrate, a body layer on the insulator, a gate and two S/D regions in the body layer beside the gate. The body connection structure of this invention includes a first control transistor and a second control transistor. The first control transistor includes a gate electrically connecting with the gate of the SOI MOS transistor, a first S/D region electrically connecting with the first S/D region of the SOI MOS transistor, and a second S/D region electrically connecting with the body layer of the SOI MOS transistor. The second control transistor includes a gate electrically connecting with the gate of the SOI MOS transistor, a first S/D region electrically connecting with the second S/D region of the SOI MOS transistor and a second S/D region electrically connecting with the body layer of the SOI MOS transistor.

In some embodiments, the SOI MOS transistor and the first and second control transistors may all be NMOS or PMOS transistors. The body connection structure may further include a resistor that is electrically connected between the body layer of the SOI MOS transistor and a charge leakage path like the substrate. In addition, the body layers of the first and second control transistors may also electrically connect with that of the SOI MOS transistor, and one example is that the SOI MOS transistor and the first and second control transistors share the same body layer.

When the above SOI MOS transistor as an NMOS transistor is at the turn-on stage, the gates of the SOI NMOS transistor and the first and second control transistors are biased high, and the body layer of the SOI NMOS transistor is quickly charged up to a voltage level between Vcc and ground (GND). Because the voltage level of the body layer is positive, the turn-on current of the NMOS transistor becomes larger.

On the other hand, when the above SOI MOS transistor as a PMOS transistor is at the turn-on stage, the gates of the PMOS transistor and the two control transistors are biased low, and the body layer of the PMOS transistor is charged down from Vcc to a voltage level between Vcc and GND. Because the voltage level of the body layer is less than Vcc, the turn-on current of the PMOS transistor become larger.

It is to be understood that both the foregoing general description and the following detailed description are exemplary, and are intended to provide further explanation of the invention as claimed.

### BRIEF DESCRIPTION OF THE DRAWINGS

FIG. 1 depicts a circuit diagram of a conventional SOI MOS transistor.

FIG. 2 depicts a circuit diagram of another conventional SOI MOS transistor together with its body connection structure.

FIG. 3 depicts a circuit diagram of an SOI MOS transistor together with its body connection structure according to an embodiment of this invention.

FIG. 4 depicts a circuit diagram of an SOI MOS transistor together with its body connection structure according to another embodiment of this invention.

FIGS. 5A and 5B respectively depict a top view and a cross-sectional view of an exemplary layout of an SOI MOS transistor together with its body connection structure according to the above embodiments of this invention.

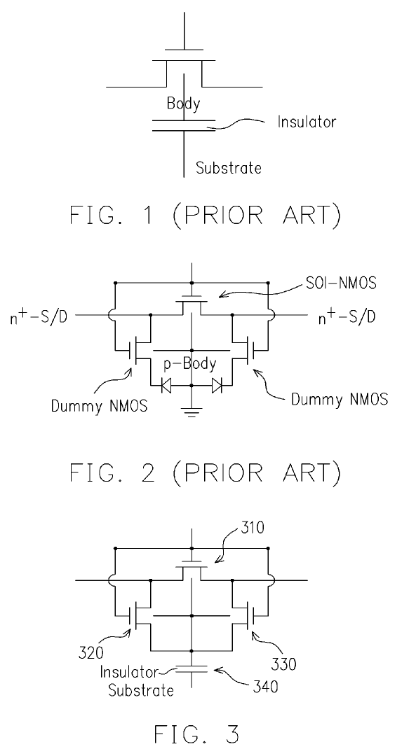

### DESCRIPTION OF THE PREFERRED EMBODIMENTS

FIG. 3 depicts a circuit diagram of an SOI MOS transistor together with its body connection structure according to an embodiment of this invention. The SOI MOS transistor 310 may be an SOI NMOS transistor or an SOI PMOS transistor. The body connection structure for the SOI MOS transistor 310 includes a first control transistor 320 and a second control transistor 330. The first control transistor 320 includes a gate electrically connecting with the gate of the SOI MOS transistor, a first S/D region electrically connecting with one S/D region of the SOI MOS transistor 310 and a second S/D region electrically connecting with the body layer of the SOI MOS transistor 310. The second control transistor 330 includes a gate electrically connecting with the gate of the SOI MOS transistor, a first S/D region electrically connecting with the other S/D region of the SOI MOS transistor 310 and a second S/D region electrically connecting with the body layer of the SOI MOS transistor. For the convenience of circuit design, the first and second control transistors 320 and 330 are preferably NMOS (or PMOS) transistors when the SOI MOS transistor 310 is an SOI NMOS (or PMOS) transistor.

In addition, the body layer of the first control transistor 320 and the body layer of the second control transistor 330 both electrically connect with the body layer of the SOI MOS transistor 310 in this embodiment. To make such a connection, it is feasible to have the SOI MOS transistor 310 and the control transistors 320 and 330 share the same body layer, i.e., to form the transistors 310, 320 and 330 based on one contiguous body layer. When the transistors 310 to 330 share the same body layer, it is possible to make one S/D region of the SOI MOS transistor 310 contiguous with the corresponding S/D region of the control transistor 320 and the other S/D region of the same contiguous with the corresponding S/D region of the control transistor 330. Moreover, the body layer, the insulator and the substrate together form a capacitor 340.

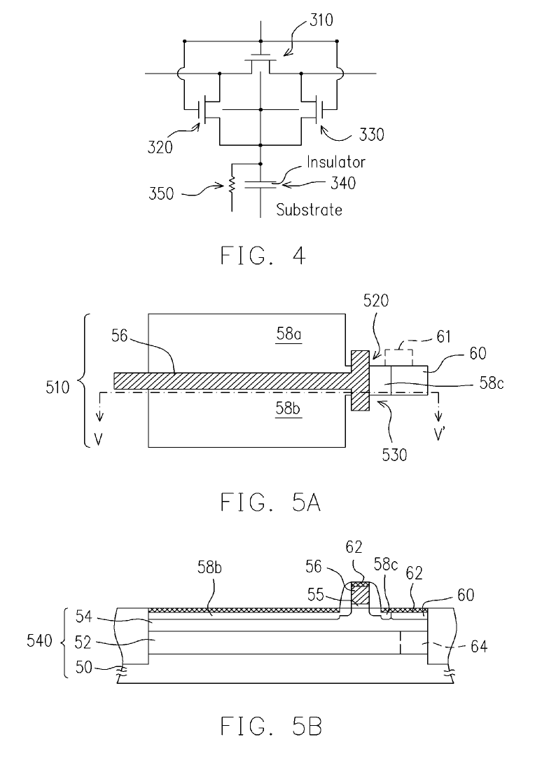

FIG. 4 depicts a circuit diagram of an SOI MOS transistor together with its body connection structure according to another embodiment of this invention. The circuit is different from that of FIG. 3 in that the body connection structure further includes a resistor 350 electrically connected between the body layer of the SOI MOS transistor 310 and the substrate as a charge leakage path. The resistor 350 is incorporated for completely leaking the charges remaining in the body layer after the turn-on stage, but preferably has a resistance as high as 10⁹Ω to 10¹²Ω so that the body layer of the SOI transistor 310 is charged effectively at the turn-on stage. The resistor 350 may be a body contact formed through the insulator to connect the body layer and the substrate, as described later.

Possible Layout of SOI MOS Transistor and Body Connection Structure

FIGS. 5A and 5B respectively depict a top view and a cross-sectional view along line V-V′ of an exemplary layout of an SOI MOS transistor together with its body connection structure according to the above embodiments of this invention. As shown in FIGS. 5A-5B, the SOI MOS transistor 510 and the control transistors 520 and 530 are formed based on the same body layer 54 disposed on an insulator 52 on a substrate 50. The body layer 54, the insulator 52 and the substrate 50 form a capacitor 540.

A T-shaped gate line 56 is formed over the body layer 54 with a gate dielectric layer in between, serving as the gates of the transistors 510, 520 and 530. Specifically, the gate of the SOI MOS transistor 510 is contiguous with the two gates of the control transistors 520 and 530 and connected to the joint of the two gates to form the T-shape gate line 56. The gates of the transistors 510-530 are thus electrically connected.

Moreover, in this example, one S/D region of the SOI MOS transistor 510 is contiguous with one S/D region of the control transistor 520 to form a doped region 58a adjacent to the gates of the transistors 510 and 520, and the other S/D region of the SOI MOS transistor 510 is contiguous with one S/D region of the control transistor 530 to form a doped region 58b adjacent to the gates of the transistors 510 and 530. In addition, the other S/D region of the control transistor 520 is contiguous with the other S/D region of the control transistor 530 to form a doped region 58c adjacent to the gates of the control transistors 520 and 530.

The doped region 58c, which is the combination of one S/D region of the control transistor 520 and one S/D region of the control transistor 530, is electrically connected to the body layer 54 to form the circuit in FIG. 3. To achieve the electrical connection in a real layout, the body layer 54 may include a portion beside the doped region 58c that has a conductivity type opposite to that of the doped region 58c but is electrically connected with the doped region 58c, as indicated by the dash line 61. The portion of the body layer 54 beside the doped region 58c may be formed with a doped region 60 of the same conductivity type of the body layer 54. The doped region 58c and the portion of the body layer 54 of different conductivity types can be electrically connected with each other via a conductor on both of them, such as a self-aligned silicide (salicide) layer 62. The salicide layer 62 may be a layer of titanium silicide, cobalt silicide or nickel silicide, and is also formed on each of the T-shaped gate line 56 and the two doped regions 58a and 58b.

Furthermore, to form the circuit shown in FIG. 4, it is possible to form a body contact 64 as the resistor 350 through the insulator 52 to electrically connect the body layer 54 and the substrate 50. The body contact 64 has a proper resistance in the range of 10⁹-10¹²Ω, so as to maintain the required potential as the control transistors 520 and 530 are at turn-on stage as well as to leak the charges effectively as the transistors 520 and 530 are at turn-off stage. The body contact 64 may include intrinsic silicon to have such resistance, while the intrinsic silicon may be formed through selective epitaxy growth from a portion of the substrate 50 exposed in the corresponding contact opening previously formed in the insulator 52.

Operation of SOI MOS Transistor and Body Connection Structure

Exemplary operations of the circuits in FIGS. 3-4 are briefly described as follows to show the effect of this invention, wherein the transistors 310-330 are simultaneously NMOS transistors or PMOS transistors.

When the SOI MOS transistor 310 as an NMOS transistor is at the turn-on stage, the gates of the transistor 310 and the control transistors 320 and 330 are biased high, and the body layer of the transistor 310 is charged up to a voltage level between Vcc and GND. Since the voltage level of the body layer is positive, the turn-on current of the transistor 310 becomes larger. At the turn-off stage, the gates of the transistors 310 to 330 go to low, and the body layer thereof discharges to GND gradually. For the body connection structure in FIG. 3, the body layer is floating at the turn-off stage; for that in FIG. 4, the body layer has a voltage level at GND more quickly.

When the SOI MOS transistor 310 as a PMOS transistor is at the turn-on stage, the gates of the transistor 310 and the control transistors 320 and 330 are biased low, and the body layer of the transistor 310 is charged down from Vcc to a voltage level between Vcc and GND. Since the voltage level of the body layer is less than Vcc, the turn-on current of the transistor 310 become larger. At the turn-off stage, the gates of the transistors 310 to 330 go to Vcc, and the body layer thereof is charged to Vcc gradually. For the body connection structure in FIG. 3, the body layer is floating at the turn-off stage; for that in FIG. 4, the voltage level of the body layer quickly becomes Vcc at the turn-off stage.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A body connection structure for a SOI MOS transistor that includes a substrate, an insulator on the substrate, a body layer on the insulator, a gate and two S/D regions in the body layer beside the gate, comprising:
a first control transistor, including a gate electrically connecting with the gate of the SOI MOS transistor, a first S/D region electrically connecting with a first S/D region of the SOI MOS transistor, and a second S/D region electrically connecting with the body layer of the SOI MOS transistor; and
a second control transistor, including a gate electrically connecting with the gate of the SOI MOS transistor, a first S/D region electrically connecting with a second S/D region of the SOI MOS transistor, and a second S/D region electrically connecting with the body layer of the SOI MOS transistor.

2. The body connection structure of claim 1, wherein the SOI MOS transistor, the first control transistor and the second control transistor are NMOS or PMOS transistors.

3. The body connection structure of claim 1, further comprising a resistor that is electrically connected between the body layer of the SOI MOS transistor and the substrate.

4. The body connection structure of claim 3, wherein the resistor has a resistance in the range of 10⁹-10¹²Ω.

5. The body connection structure of claim 3, wherein the resistor comprises a body contact through the insulator to the substrate.

6. The body connection structure of claim 5, wherein the body contact comprises intrinsic silicon.

7. The body connection structure of claim 1, wherein a body layer of the first control transistor and a body layer of the second control transistor both are electrically connected with the body layer of the SOI MOS transistor.

8. The body connection structure of claim 7, wherein the SOI MOS transistor, the first control transistor and the second control transistor share the same body layer.

9. The body connection structure of claim 8, wherein
the first S/D region of the SOI MOS transistor is contiguous with the first S/D region of the first control transistor to form a first doped region; and
the second S/D region of the SOI MOS transistor is contiguous with the first S/D region of the second control transistor to form a second doped region.

10. The body connection structure of claim 9, wherein
the gate of the SOI MOS transistor is contiguous with the gate of the first control transistor and the gate of the second control transistor;
the first doped region is adjacent to the gate of the SOI MOS transistor and the gate of the first control transistor;
the second doped region is adjacent to the gate of the SOI MOS transistor and the gate of the second control transistor; and
the second S/D region of the first control transistor is contiguous with the second S/D region of the second control transistor to form a third doped region adjacent to the gate of the first control transistor and the gate of the second control transistor.

11. The body connection structure of claim 10, wherein the body layer includes a portion having a conductivity type opposed to that of the third doped region beside the third doped region, the portion of the body layer being electrically connected with the third doped region via a conductor on both of the portion of the body layer and the third doped region.

12. The body connection structure of claim 11, wherein the conductor comprises a salicide layer.

13. The body connection structure of claim 11, wherein the portion of the body layer is formed with a doped region of the conductivity type therein.

14. The body connection structure of claim 10, further comprising a body contact through the insulator to the substrate, the body contact serving as a resistor.

15. The body connection structure of claim 14, wherein the resistor has a resistance in the range of 10⁹-10¹²Ω.

16. The body connection structure of claim 14, wherein the body contact comprises intrinsic silicon.
